(19) United States
(12) Patent Application Publication
(10) Pub. No.: US 2025/0340996 A1
(43) Pub. Date: Nov. 6, 2025

(54) TRANSPARENT METAL OXIDE SUBSTRATE AND MANUFACTURING METHOD THEREOF

(71) Applicant: KOREA UNIVERSITY RESEARCH AND BUSINESS FOUNDATION, Seoul (KR)

(72) Inventor: Yoonmook KANG, Seoul (KR)

(73) Assignee: KOREA UNIVERSITY RESEARCH AND BUSINESS FOUNDATION, Seoul (KR)

(21) Appl. No.: 19/268,498

(22) Filed: Jul. 14, 2025

Related U.S. Application Data
(63) Continuation of application No. PCT/KR2024/002987, filed on Mar. 8, 2024.

(30) Foreign Application Priority Data
Mar. 10, 2023 (KR) 10-2023-0031917
Mar. 6, 2024 (KR) 10-2024-0031807

(51) Int. Cl. C23C 28/04

(52) U.S. Cl. CPC C23C 28/04

(57) ABSTRACT

The present invention relates to a transparent metal oxide substrate and a method of manufacturing the same, and particularly, to a low-reflective coating and anti-fouling coating technology. According to an embodiment, it is possible to provide a transparent metal oxide substrate including: a transparent substrate; and an aluminum compound bilayer consisting of a first coating layer disposed on the transparent substrate with a refractive index of n1 as a high refractive index compound layer and a second coating layer disposed on the first coating layer with a refractive index of n2 as a low refractive index compound layer, and wherein the refractive indices satisfy a condition of n1>n2.

### CROSS-REFERENCE TO RELATED APPLICATION(S)

Pursuant to 35 USC 120 and 365(c), this application is a continuation of International Application No. PCT/KR2024/002987 filed on Mar. 8, 2024, and claims the benefit under 35 USC 119(a) of Korean Application No. 10-2023-0031917 filed on Mar. 10, 2023 and Korean Application No. 10-2024-0031807 filed on Mar. 6, 2024, in the Korean Intellectual Property Office, the entire disclosure of which is incorporated herein by reference for all purposes.

### TECHNICAL FIELD

The present invention relates to a transparent metal oxide substrate and a method of manufacturing the same, and particularly, to a low-reflective coating and anti-fouling coating technology.

### STATEMENT REGARDING GOVERNMENT SPONSORED RESEARCH OR DEVELOPMENT

The present invention was derived from research conducted as part of the Ministry of Trade, Industry and Energy's New and Renewable Energy Core Technology Development (Electricity) (Project Identification No.: 1415180654, Sub-Project No.: 20213030010400, Research Project Title: Development of High-Durability and High-Efficiency Perovskite/Crystalline Silicon Tandem Solar Module Process Technology, Institute of Organization: Hanwha Solutions Corporation, Research Period: May 1, 2022 to Dec. 31, 2022).

The present invention was derived from research conducted as part of the Ministry of Trade, Industry and Energy's New and Renewable Energy Core Technology Development (Electricity) (Project Identification No.: 2410000209, Sub-Project No.: 00236664, Research Project Title: Development of All-Inorganic Thermally-Induced Phase Change Perovskite Top Cell and Core Material for Application to Crystalline Silicon-Based Tandem Solar Cell, Institute of Organization: Chungnam National University Industry-Academic Collaboration Foundation, Research Period: Jan. 1, 2024 to Dec. 31, 2024).

Meanwhile, in all the aspects of the inventive concept, there is no property interest in the government of the Republic of Korea.

### BACKGROUND ART

In general, in a case of solar cells, displays and camera lenses, a low-reflective coating on a surface is performed to secure a low-reflectance property, and accordingly, coating technology using aluminum and aluminum oxide has been studied as follows.

As an example, research has been conducted to reduce reflectance by coating oxide or nitride on a silicon substrate with sub-micrometer roughness in a solar cell field, and by coating multilayer oxides in a lens field.

As another example, research has been conducted to secure transparency by coating an aluminum thin film on a substrate and then creating micro-holes through which light may be transmitted or oxidizing some regions of aluminum, and as yet another example, research was conducted to manufacture a transparent substrate in a metal/oxide structure without oxidizing the aluminum.

However, the above researches have limitations in that it is difficult to secure transparency because opaque aluminum remains, and furthermore, it is difficult to effectively create a nanometer-sized aluminum oxide uneven structure or a desired specific refractive index change.

In addition, since the above researches are conducted in a multilayer structure, it is difficult to secure economic benefits due to a complexity of a manufacturing process, and it is difficult to minimize contaminant adsorption even when the low-reflectance property is secured.

Accordingly, there is a need for research on a technology that is economical and may secure low reflectance and anti-fouling property through a simple manufacturing process.

### DISCLOSURE

### Technical Problem

A transparent metal oxide substrate and a method of manufacturing the same according to an embodiment of the present invention have been proposed to solve the above-described problems and may secure low reflectance and anti-fouling property simultaneously and secure a gradual reflective index change property.

### Technical Solution

According to an embodiment, it is possible to provide a transparent metal oxide substrate including: a transparent substrate; and an aluminum compound bilayer consisting of a first coating layer disposed on the transparent substrate with a refractive index of n1 as a high refractive index compound layer and a second coating layer disposed on the first coating layer with a refractive index of n2 as a low refractive index compound layer, and wherein the refractive indices satisfy a condition of n1>n2.

In addition, it is possible to provide the transparent metal oxide substrate in which the aluminum compound bilayer is formed by phase-changing an aluminum raw material layer deposited on the transparent substrate through an oxidation process using De-ionized (DI) water.

In addition, it is possible to provide the transparent metal oxide substrate in which the n1 is 1.6 to 1.7, and the n2 is 1.1 to 1.5.

In addition, it is possible to provide the transparent metal oxide substrate in which the first coating layer has a thickness satisfying a range of 10 to 100 nm, and the second coating layer has a thickness satisfying a range of 50 to 500 nm.

In addition, it is possible to provide the transparent metal oxide substrate in which the second coating layer has a random nano-flake structure consisting of a plurality of unit flakes of which a width gradually decreases toward an upper side thereof.

In addition, it is possible to provide the transparent metal oxide substrate in which as the second coating layer has the random nano-flake structure, a refractive index continuously decreases toward the upper side thereof.

In addition, it is possible to provide the transparent metal oxide substrate in which the first coating layer and the second coating layer include at least one material selected from a group consisting of aluminum oxide and aluminum hydroxide.

In addition, it is possible to provide the transparent metal oxide substrate in which the first coating layer is an aluminum oxide thin film layer, and the second coating layer is an aluminum oxide nanostructure layer.

In addition, it is possible to provide the transparent metal oxide substrate in which the first coating layer is a polycrystalline aluminum oxide thin film layer with a grain boundary, and the second coating layer is a polycrystalline aluminum oxide nanostructure layer with a grain boundary.

According to an embodiment, it is possible to provide a method of manufacturing a transparent metal oxide substrate including: a first step of preparing a transparent substrate; a second step of depositing an aluminum raw material layer on the prepared transparent substrate; and a third step of forming an aluminum compound bilayer by phase-changing the deposited aluminum raw material layer through an oxidation process using DI water.

In addition, it is possible to provide the method of manufacturing the transparent metal oxide substrate in which the third step includes immersing the transparent substrate on which the aluminum raw material layer is deposited in the DI water at 50 to 100° C. and then maintaining for a predetermined immersion time.

In addition, it is possible to provide the method of manufacturing the transparent metal oxide substrate in which the aluminum compound bilayer consists of a first coating layer disposed on the transparent substrate with a refractive index of n1 as a high refractive index compound layer and a second coating layer disposed on the first coating layer with a refractive index of n2 as a low refractive index compound layer, and wherein the refractive indices satisfy a condition of n1>n2.

### Advantageous Effects

A transparent metal oxide substrate and a method of manufacturing the same according to an embodiment of the present invention can secure low reflectance and anti-fouling property simultaneously and secure a gradual reflective index change property.

### DESCRIPTION OF DRAWINGS

FIG. 1 is a view for describing a transparent metal oxide substrate according to an embodiment of the present invention.

FIG. 2 is a view for describing a transparent metal oxide substrate according to an embodiment of the present invention in detail.

FIG. 3 is a flowchart for describing a method of manufacturing a transparent metal oxide substrate according to an embodiment of the present invention.

FIG. 4 is an SEM image of a transparent metal oxide substrate according to Example 1.

FIG. 5 is a graph showing an XRD analysis result of an aluminum compound bilayer according to Example 1.

FIG. 6 is an SEM image of a transparent metal oxide substrate according to Comparative Example 1 and Example 1.

FIG. 7 is an SEM image of a transparent metal oxide substrate according to Comparative Example 2 and Example 1.

FIG. 8 is an SEM image of a transparent metal oxide substrate according to Example 4.

FIG. 9 is a reflectance measurement result of a transparent metal oxide substrate according to Example 2.

FIG. 10 is a reliability evaluation result of a transparent metal oxide substrate according to Comparative Example 3 and Example 3.

### MODES OF THE INVENTION

Preferred embodiments of the present invention will be described in detail with reference to the attached drawings in order to fully understand the configuration and effects of the present invention.

The present invention is not limited to the embodiments disclosed herein, but can be implemented in various forms and be subject to various modifications and changes. However, the present invention is provided solely to ensure that the disclosure of the present invention is complete through the description of the present embodiments and to fully inform those having ordinary skill in the art of the scope of the invention. The components in the attached drawings are enlarged from their actual size for convenience of the description, and the proportions of each component may be exaggerated or reduced.

The terms used herein is for the purpose of describing the embodiments only and is not intended to be limiting of the invention. In addition, the terms used herein may be interpreted as having a meaning commonly known to those having ordinary skill in the art unless otherwise defined. In addition, as used herein, the singular forms may include the plural forms unless the context clearly dictates otherwise. The terms “comprises” and/or “comprising” used herein specify the presence of a referenced component, step, operation, and/or element, but do not exclude the presence or addition of one or more other components, steps, operations, and/or elements.

In the present specification, when a layer is referred as being ‘on’ another layer, it may be formed directly on the surface of the other layer, or there may be a third layer interposed therebetween. As used herein, the terms first, second, etc. are used to describe various regions, layers, etc., but these regions and layers should not be limited by these terms. These terms are only used to distinguish one region or layer from another. Thus, a part referred to as a first part in one embodiment may be referred to as a second part in another embodiment. The embodiments described and exemplified herein also include complementary embodiments thereof. Like reference numerals may refer to like or corresponding components throughout the specification.

In the present invention, a transparent metal oxide substrate with both a low reflectance and an anti-fouling property was secured by disposing aluminum compound coating layer with different refractive indices on a substrate.

Specifically, the transparent metal oxide substrate of the present invention is designed to be manufactured by depositing an aluminum thin film on the substrate and then performing an oxidation process using De-ionized (DI) water.

### Transparent Metal Oxide Substrate

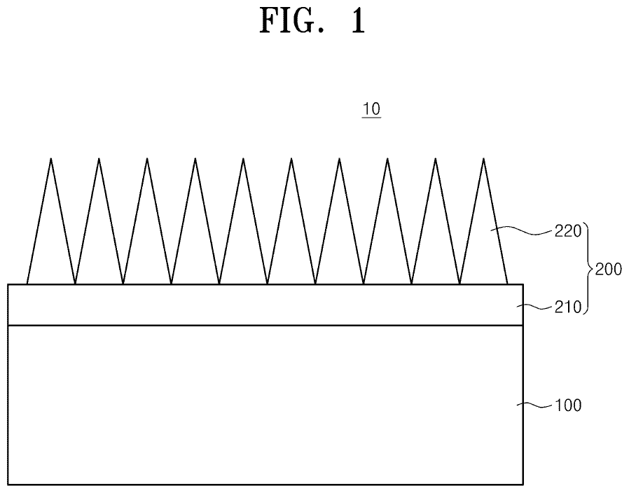

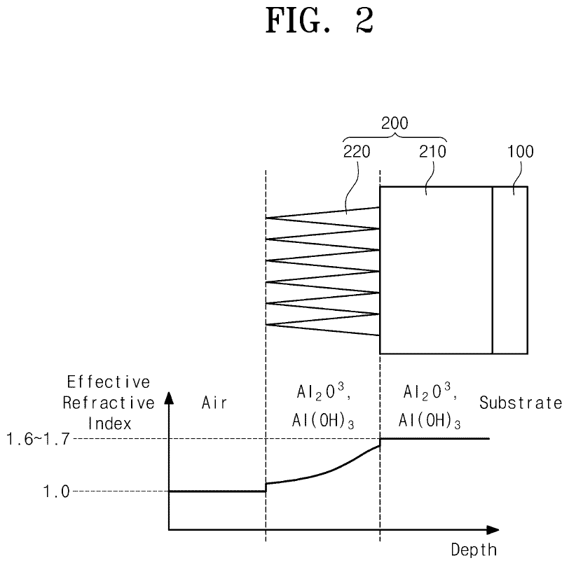

FIG. 1 is a view for describing a transparent metal oxide substrate according to an embodiment of the present invention, and FIG. 2 is a view for describing the transparent metal oxide substrate according to an embodiment of the present invention in detail.

Referring to FIGS. 1 and 2, a transparent metal oxide substrate 10 according to an embodiment of the present invention may include a transparent substrate 100 and an aluminum compound bilayer 200 consisting of a first coating layer 210 disposed on the transparent substrate 100 with a refractive index of n1 as a high refractive index compound layer, and a second coating layer 220 disposed on the first coating layer 210 with a refractive index of n2 as a low refractive index compound layer.

Here, the refractive indices of the first coating layer 210 and the second coating layer 220 may satisfy a condition of n1>n2, and accordingly, the transparent metal oxide substrate 10 may include a bilayer coating of a high refractive index layer (the first coating layer)-low refractive index layer (the second coating layer).

The transparent metal oxide substrate 10 may be utilized in solar cells, displays, and camera lenses. Meanwhile, when utilizing in camera lenses, the transparent metal oxide substrate 10 may further include a silicon oxide thin film layer 300 disposed between the aluminum compound bilayer 200 and the transparent substrate 100.

The transparent substrate 100 may be a glass substrate, a transparent plastic substrate, or a combination thereof.

A common glass such as a soda-lime glass, a low iron plate glass, or the like may be used as the glass substrate, but it is not limited thereto.

A substrate made of a polymer material selected from polycarbonate, polymethylmethacrylate, polyethylene terephthalate, polybutylene terephthalate, polyimide, bakelite, polyvinyl butyral, and combinations thereof may be used as the transparent plastic substrate.

The aluminum compound bilayer 200 may be formed by phase-changing an aluminum raw material layer deposited on the transparent substrate 100 through an oxidation process using DI water.

Here, the aluminum raw material layer may be an aluminum thin film.

In addition, the aluminum raw material layer may be a low-oxygen-containing aluminum oxide thin film with an oxygen content lower than that of general aluminum oxide (Al₂O₃), or a low-oxygen-containing aluminum hydroxide thin film with an oxygen content lower than that of general aluminum hydroxide (Al(OH)₃).

In addition, the aluminum raw material layer may be a thin film including both the low-oxygen-containing aluminum oxide with an oxygen content lower than that of the general aluminum oxide (Al₂O₃) and the low-oxygen-containing aluminum hydroxide with an oxygen content lower than that of the general aluminum hydroxide (Al(OH)₃).

Preferably, as the aluminum raw material layer, an aluminum compound with an oxygen content higher than that of a general aluminum thin film and an oxygen content lower than that of the general aluminum oxide (Al₂O₃) or aluminum hydroxide (Al(OH)₃) may be used without particular limitations.

The oxidation process may include at least one process selected from a process of immersing the aluminum raw material layer deposited on the transparent substrate 100 in the DI water and then maintaining the same for a predetermined immersion time, and a process of maintaining the aluminum raw material layer deposited on the transparent substrate 100 for a predetermined exposure time in a high temperature-high humidity atmosphere.

Accordingly, the aluminum raw material layer may be phase-changed through the oxidation process, and for example, the aluminum thin film may be phase-changed into a thin film including at least one material of Al₂O₃ and Al(OH₃).

The first coating layer 210 and the second coating layer 220 may be aluminum compound layers with refractive indices of n1 and n2, respectively.

The n1 may preferably be 1.6 to 1.7, and the n2 may preferably be 1.1 to 1.5.

It is preferable for the first coating layer 210 to have a thickness satisfying a range of 10 to 100 nm, and when the thickness is thinner than 1 nm, there may be a limitation to expressing a low-reflectance property, and at the same time, a contact area between the substrate and the compound decreases which may weaken an adhesive strength. In addition, when the thickness is thicker than 100 nm, it may be difficult for water of a gaseous phase or a liquid phase inside the substrate to escape to the outside.

It is preferable for the second coating layer 220 to have a thickness satisfying a range of 50 to 500 nm, and when the thickness is thinner than 50 nm, there may be a limitation in expressing an anti-fouling property, and at the same time, it may be difficult to express a property of lowering the refractive index. In addition, when the thickness is thicker than 500 nm, a durability may be significantly reduced due to structural instability, and furthermore, an unchanged aluminum raw material layer may remain.

In addition, the second coating layer 220 may have a random nano-flake structure consisting of a plurality of unit flakes of which a width gradually decreases toward an upper side thereof.

In addition, as the second coating layer 220 has the random nano-flake structure, the refractive index may continuously decrease toward the upper side thereof.

The term “progressively” as used herein indicates that the width of the unit flakes decreases continuously, indicating that the refractive index decreases continuously. For example, when a plurality of layers with different refractive indices are bonded together, the refractive indices are maintained uniformly with a constant value in each layer, and there is a rapid change in the refractive indices in a step shape at bonding surfaces. In contrast, in the present invention, the expression “gradually” indicates that the refractive index decreases continuously in a curved shape in the second coating layer 220, and that the change in the refractive index is minimized and thus changing gradually even at the bonding surface where the plurality of thin film layers are bonded with each other, and the term is particularly used to indicate that the refractive index changes gradually inside a single layer. The second coating layer 220 may be uneven in density or uneven in shape and form inside the single layer.

Meanwhile, the first coating layer 210 and the second coating layer 220 may include at least one material selected from a group consisting of aluminum oxide (Al2O3) and aluminum hydroxide (Al(OH₃)).

Preferably, the first coating layer 210 may be an aluminum oxide (Al₂O₃) thin film layer, and the second coating layer 220 may be an aluminum oxide (Al₂O₃) nanostructure layer.

More specifically, the first coating layer 210 may be a polycrystalline aluminum oxide thin film layer with a grain boundary, and the second coating layer 220 may be a polycrystalline aluminum oxide nanostructure layer with a grain boundary, and a size of the grain is not particularly limited, but it is preferably in a nanometer scale.

Here, the grain boundary may provide a path for the water of the gaseous phase or the liquid phase inside the transparent substrate 100 to escape to the outside when the transparent metal oxide substrate 10 of the present invention is exposed to the high temperature-high humidity environment.

Accordingly, there is an effect of reducing an occurrence rate of defects including blisters, blister stains, and cracks that are likely to occur in the second coating layer 220 or on the bonding surface between the second coating layer 220 and the transparent substrate 100.

Meanwhile, as described above, in a transparent metal oxide substrate 10 according to another embodiment of the present invention, the transparent metal oxide substrate 10 may further include a silicon oxide (SiO₂) thin film layer 300.

The silicon oxide thin film layer 300 may be deposited between the transparent substrate 100 and the aluminum compound bilayer 200 and serve to improve the low-reflectance property of the transparent metal oxide substrate 10.

### Method of Manufacturing a Transparent Supercapacitor Electrode

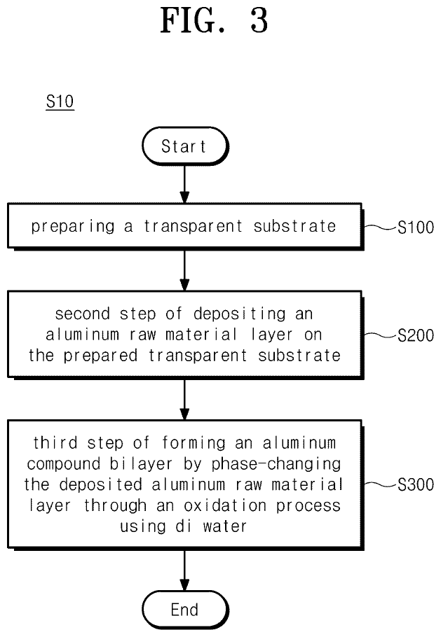

FIG. 3 is a flowchart for describing a method of manufacturing a transparent metal oxide substrate according to an embodiment of the present invention.

The method of manufacturing is described with reference to the above-described transparent metal oxide substrate. The description of the present manufacturing method may be essentially combined with the description of the above-described transparent metal oxide substrate.

Referring to FIG. 3, a method of manufacturing a transparent metal oxide substrate S10 according to an embodiment of the present invention may include a first step S100 of preparing a transparent substrate, a second step S200 of depositing an aluminum raw material layer on the prepared transparent substrate, and a third step S300 of forming an aluminum compound bilayer by phase-changing the deposited aluminum raw material layer through an oxidation process using DI water.

In the first step S100, a substrate consisting of a glass substrate, a transparent plastic substrate, or a combination thereof may be prepared.

A common glass such as a soda-lime glass, a low iron plate glass, or the like may be used as the glass substrate, but it is not limited thereto.

A substrate made of a polymer material selected from polycarbonate, polymethylmethacrylate, polyethylene terephthalate, polybutylene terephthalate, polyimide, bakelite, polyvinyl butyral, and combinations thereof may be used as the transparent plastic substrate.

In the second step S200, the aluminum raw material layer may be coated on the substrate.

A method of depositing the aluminum raw material layer on the transparent substrate in the second step S200 is not particularly limited, but it may be deposited by physical vapor deposition (PVD) including thermal deposition, ALD, vacuum deposition, and sputtering in particular or chemical vapor deposition (CVD) including low pressure, atmospheric pressure, and plasma.

In addition, in the second step S200, it is preferable that the aluminum raw material layer has a thickness satisfying a range of 30 to 300 nm.

In the third step S300, the transparent substrate on which the aluminum raw material layer is deposited may be immersed in the DI water or exposed to a high temperature-high humidity environment to produce the transparent metal oxide substrate with a stacked structure consisting of the aluminum compound bilayer/transparent substrate including the first coating layer and the second coating layer.

Specifically, in an embodiment of the present invention, the third step S300 may include immersing the transparent substrate on which the aluminum raw material layer is deposited in the DI water at 50 to 100° C. and then maintaining for a predetermined immersion time.

More specifically, in the immersing in the DI water, the predetermined immersion time may be 1 to 60 minutes.

In addition, in another embodiment of the present invention, the third step S300 may include exposing the transparent substrate on which the aluminum raw material layer is deposited for a predetermined exposure time in a high temperature-high humidity atmosphere of 60 to 80° C. and a relative humidity of 70 to 90%.

In the exposing the transparent substrate for a predetermined time in the high temperature-high humidity atmosphere, the predetermined time may be 1 to 60 minutes.

That is, the third step S300 may include at least one process selected from a process of immersing the aluminum raw material layer deposited on the transparent substrate in the DI water and then maintaining the same for a predetermined immersion time, and a process of maintaining the aluminum raw material layer deposited on the transparent substrate for a predetermined exposure time in a high temperature-high humidity atmosphere.

Accordingly, in the third step S300, an oxidation reaction of the aluminum raw material layer occurs, thereby forming the first coating layer in a horizontal direction and then forming the second coating layer in a vertical direction, that is, the aluminum compound bilayer consisting of the first coating layer and the second coating layer may be formed.

Specifically, the aluminum compound bilayer may consist of the first coating layer disposed on the transparent substrate with a refractive index of n1 as a high refractive index compound layer and a second coating layer disposed on the first coating layer with a refractive index of n2 as a low refractive index compound layer, and the refractive indices of the first coating layer and the second coating layer satisfy a condition of n1>n2.

Meanwhile, a method of manufacturing the transparent metal oxide substrate S10 according to another embodiment of the present invention may further include depositing a silicon oxide thin film layer on the prepared transparent substrate before the second step S200.

Accordingly, the aluminum raw material layer may be deposited on the prepared transparent substrate, more specifically, on the silicon oxide thin film layer.

### Example 1. Manufacturing of Transparent Metal Oxide Substrate 1

S100: First, a polycarbonate substrate (hereinafter, PC substrate) is prepared.

Next, a silicon oxide (SiO₂) thin film layer is deposited on the prepared PC

substrate. In this case, a thickness of the silicon oxide thin film layer may be 90 to 100 nm.

S200: An aluminum (Al) thin film layer that is an aluminum raw material layer is deposited on the PC substrate on which the silicon oxide thin film layer is deposited.

In this case, a thickness of the deposited aluminum thin film layer may be 300 nm.

S300: The PC substrate on which the aluminum thin film layer is deposited is immersed in DI water at 90° C. for 5 minutes to manufacture the transparent metal oxide substrate (Example 1).

### Example 2. Manufacturing of Transparent Metal Oxide Substrate 2

Example 2 was carried out in the same manner as the Example 1 except for replacing the process of immersing the PC substrate on which the aluminum thin film layer is deposited in the DI water at 90° C. for 5 minutes in the step S300 of Example 1 with a process of immersing the PC substrate on which the aluminum thin film layer is deposited in the DI water at 90° C. for 1 to 7 minutes.

Here, a transparent metal oxide substrate immersed in the DI water for 1 minute is sample A of Example 2, a transparent metal oxide substrate immersed in the DI water for 2 minutes is sample B of Example 2, a transparent metal oxide substrate immersed in the DI water for 3 minutes is sample C of Example 2, a transparent metal oxide substrate immersed in the DI water for 4 minutes is sample D of Example 2, a transparent metal oxide substrate immersed in the DI water for 5 minutes is sample E of Example 2, a transparent metal oxide substrate immersed in the DI water for 6 minutes is sample F of Example 2, and a transparent metal oxide substrate immersed in the DI water for 7 minutes is sample G of Example 2.

### Example 3. Manufacturing of Transparent Metal Oxide Substrate 3

Example 3 was carried out in the same manner as the Example 1 except for replacing the process of depositing the aluminum (Al) thin film layer that is the aluminum raw material layer on the PC substrate on which the silicon oxide thin film layer is deposited to a thickness of 300 nm in the step S200 of Example 1 with a process of depositing the aluminum (Al) thin film layer that is the aluminum raw material layer on the PC substrate on which the silicon oxide thin film layer is deposited to a thickness of 45 nm and except for depositing the silicon oxide thin film layer to a thickness of 75 nm.

### Example 4. Manufacturing of Transparent Metal Oxide Substrate 4

Example 4 was carried out in the same manner as the Example 1 except for performing the process of depositing the silicon oxide (SiO₂) thin film layer on the prepared PC substrate in the Example 1.

### Comparative Example 1. Manufacturing of Transparent Metal Oxide Substrate 5

Comparative Example 1 was carried out in the same manner as the Example 1 except for replacing the process of depositing the aluminum (Al) thin film layer that is the aluminum raw material layer on the PC substrate on which the silicon oxide thin film layer is deposited in the step S200 of Example 1 with a process of depositing an aluminum oxide (Al₂O₃) thin film layer that is the aluminum raw material layer on the PC substrate on which the silicon oxide thin film layer is deposited.

### Comparative Example 2. Manufacturing of Transparent Metal Oxide Substrate 6

A previously known multilayer thin film was prepared. The known multilayer thin film includes at least one material selected from silicon oxide, titanium oxide, and a combination thereof.

### Comparative Example 3. Manufacturing of Transparent Metal Oxide Substrate 7

Comparative Example 3 was carried out in the same manner as the Example 1 except for replacing the process of depositing the aluminum (Al) thin film layer that is the aluminum raw material layer on the PC substrate on which the silicon oxide thin film layer is deposited to a thickness of 300 nm in the step S200 of Example 1 with a process of depositing the aluminum oxide (Al₂O₃) thin film layer that is the aluminum raw material layer on the PC substrate on which the silicon oxide thin film layer is deposited to a thickness of 45 nm and except for depositing the silicon oxide thin film layer to a thickness of 75 nm.

### Experimental Example 1. Evaluation of Microstructure 1

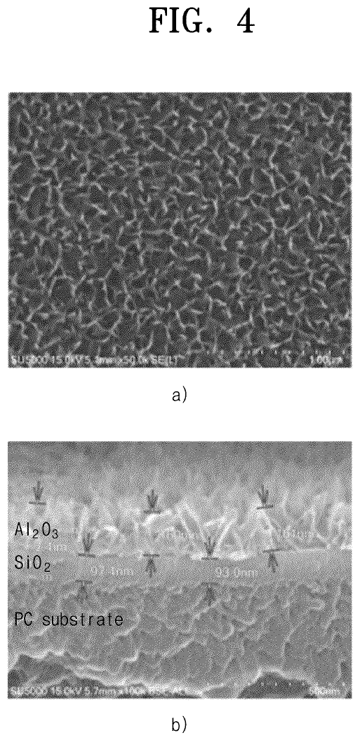

In order to evaluate a stacked structure and a microstructure of a coating film in the transparent metal oxide substrate according to Examples of the present invention, the microstructure for the Example 1 was observed with a scanning electron microscope (SEM) and results are shown in FIG. 4.

FIG. 4 is an SEM image of the transparent metal oxide substrate according to Example 1.

FIG. 4A is a plan view of the transparent metal oxide substrate according to Example 1, and FIG. 4B is a cross-sectional view of the transparent metal oxide substrate according to Example 1.

Referring to FIG. 4, it may be confirmed that the transparent metal oxide substrate according to Example 1 consists of the PC substrate/silicon oxide thin film layer/aluminum compound bilayer, and that the aluminum thin film is converted into a thin film with a random nano-flake structure consisting of a plurality of unit flakes of which a width gradually decreases toward an upper side thereof.

### Experimental Example 2. XRD Analysis

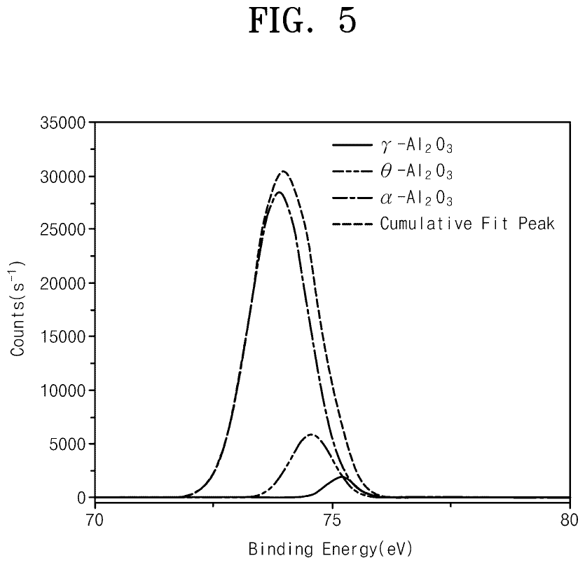

In order to confirm a phase change according to the oxidation reaction using the DI water in the transparent metal oxide substrate according to Examples of the present invention, an XRD analysis was performed on the aluminum compound bilayer of the Example 1 and results are shown in FIG. 5.

FIG. 5 is a graph showing an XRD analysis result of the aluminum compound bilayer according to Example 1.

Referring to FIG. 5, it was confirmed that the aluminum compound bilayer including the first coating layer and the second coating layer consists of Al₂O₃ phase, more specifically, α-Al₂O₃ phase, β-Al₂O₃ phase, and γ-Al₂O₃ phase.

### Experimental Example 3. Evaluation of Microstructure 2

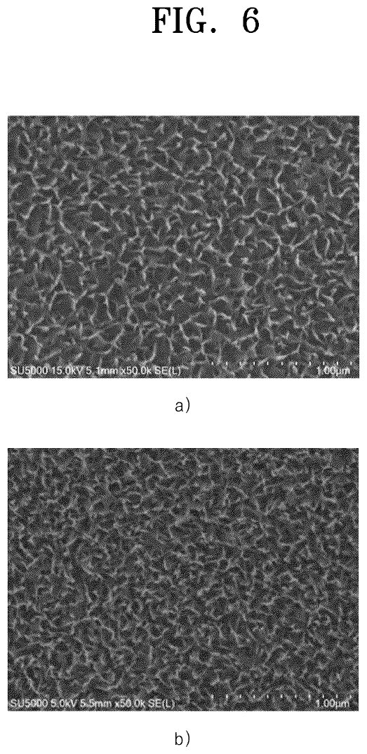

In order to evaluate the stacked structure and the microstructure of the coating film of Example 1 and Comparative Example 1 in the transparent metal oxide substrate according to Examples of the present invention, the microstructures of the Comparative Example 1 and Example 1 were observed with the scanning electron microscope (SEM) and results are shown in FIG. 6.

FIG. 6 is an SEM image of the transparent metal oxide substrate according to Comparative Example 1 and Example 1.

FIG. 6A is a plan view of the transparent metal oxide substrate according to Comparative Example 1, and FIG. 6B is a plan view of the transparent metal oxide substrate according to Example 1.

Referring to FIG. 6, it was confirmed that nano flakes with smaller size and higher density were formed in Example 1 in which the aluminum thin film was phase-changed through the oxidation process using the DI water.

### Experimental Example 4. Evaluation of Microstructure 3

In order to evaluate the stacked structure and the microstructure of the coating

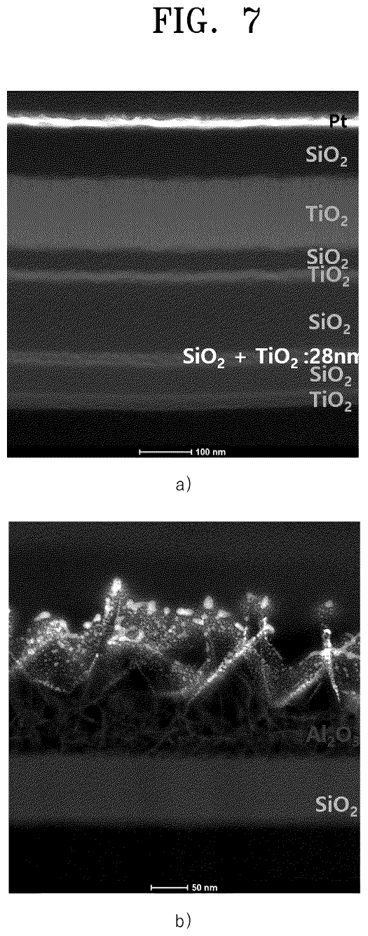

film of Example 1 and Comparative Example 2 in the transparent metal oxide substrate according to Examples of the present invention, the microstructures of the Comparative Example 2 and Example 1 were observed with the scanning electron microscope (SEM) and results are shown in FIG. 7.

FIG. 7 is an SEM image of the transparent metal oxide substrate according to Comparative Example 2 and Example 1.

FIG. 7A is a cross-sectional view of the transparent metal oxide substrate according to Comparative Example 2, and FIG. 7B is a plan view of the transparent metal oxide substrate according to Example 1.

Referring to FIG. 7, it may be confirmed that in a case of Example 1, the transparent metal oxide substrate has a simplified stacked structure consisting of the substrate/silicon oxide thin film layer/aluminum compound bilayer unlike Comparative Example 2 that is a conventional anti-reflection film.

### Experimental Example 5. Evaluation of Microstructure 4

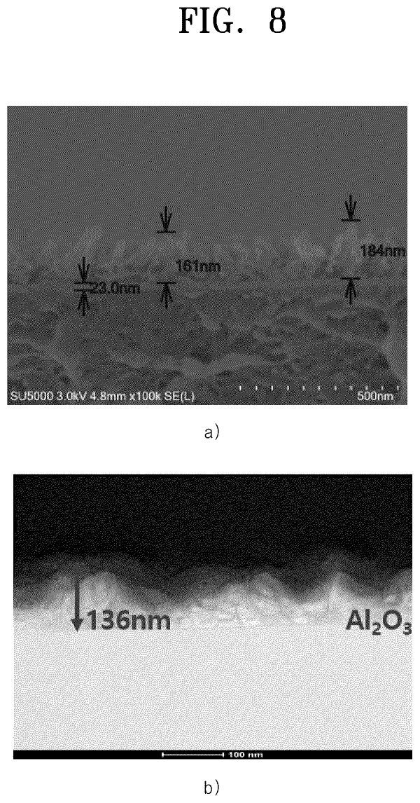

In order to evaluate the stacked structure and the microstructure of the coating film of Example 4 in the transparent metal oxide substrate according to Examples of the present invention, the microstructure of the Example 4 was observed with the scanning electron microscope (SEM) and results are shown in FIG. 8.

FIG. 8 is an SEM image of the transparent metal oxide substrate according to Example 4.

FIG. 8A is a low magnification SEM image, and FIG. 8B is a high magnification SEM image.

Referring to FIG. 8, the aluminum compound bilayer formed through the oxidation reaction of the aluminum thin film may be confirmed, and it may be confirmed that the aluminum compound bilayer consists of the aluminum oxide thin film layer that is the first coating layer and the aluminum oxide nanostructure layer that is the second coating layer.

In addition, it was confirmed that the aluminum oxide thin film layer and the aluminum oxide nanostructure layer have a polycrystalline structure with a grain boundary.

### Experimental Example 6. Evaluation of Reflectance

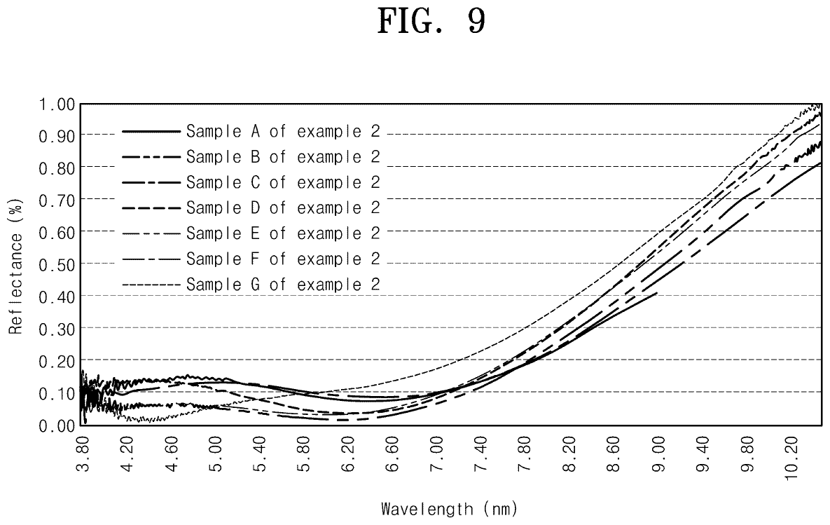

A reflectance of samples A to G of Example 2 was evaluated at a wavelength range from 300 to 1000 nm in the transparent metal oxide substrate according to Examples of the present invention and the results are shown in FIG. 9.

FIG. 9 is a reflectance measurement result of the transparent metal oxide substrate according to Example 2.

Referring to FIG. 9, it was confirmed that the samples A to G of Example 2 had values less than 0.2% at a wavelength of 380 to 700 nm corresponding to a visible light wavelength range.

### Experimental Example 7. Reliability Evaluation According to External Environment

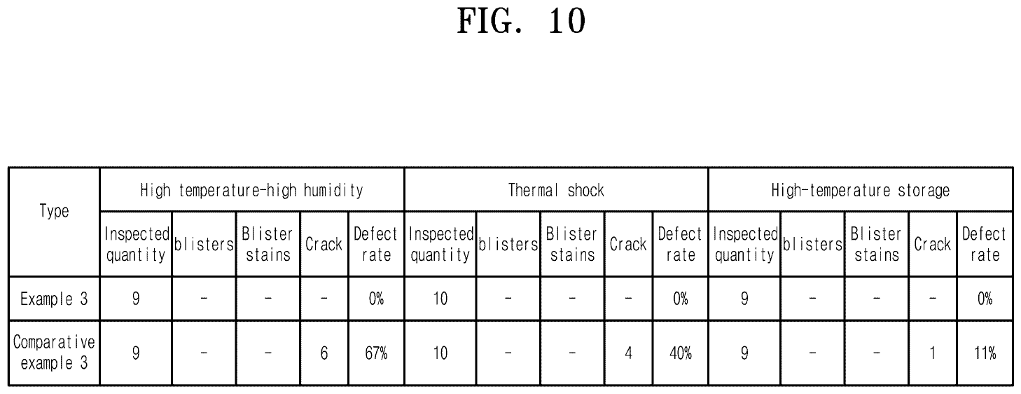

A reliability evaluation was conducted according to an external environment including high temperature-high humidity, thermal shock, and high-temperature storage of Comparative Example 3 and Example 3 in the transparent metal oxide substrate according to Examples of the present invention and results are shown in FIG. 10.

FIG. 10 is a reliability evaluation result of the transparent metal oxide substrate according to Comparative Example 3 and Example 3.

Referring to FIG. 10, in a case of Example 3 in which the aluminum thin film was phase-changed through the oxidation process using the DI water, it was confirmed that no defects occurred even in the high temperature-high humidity environment, the thermal shock environment, and the high-temperature storage environment.

Although the transparent metal oxide substrate and the method of manufacturing the same according to the embodiments of the present invention have been described as specific embodiments, it is merely an example, and the present invention is not limited thereto and it should be interpreted to have the broadest scope in accordance with the basic idea disclosed in this specification. Those skilled in the art may combine and substitute the disclosed embodiments to implement embodiments not specified, but this also does not depart from the scope of the present invention. In addition, those skilled in the art may easily change or modify the disclosed embodiments based on this specification, and it is clear that such changes or modifications also fall within the scope of the present invention.

1. A transparent metal oxide substrate comprising:
a transparent substrate; and
an aluminum compound bilayer consisting of a first coating layer disposed on the transparent substrate with a refractive index of n1 as a high refractive index compound layer and a second coating layer disposed on the first coating layer with a refractive index of n2 as a low refractive index compound layer, and wherein the refractive indices satisfy a condition of n1>n2.

2. The transparent metal oxide substrate of claim 1,
wherein the aluminum compound bilayer is formed by phase-changing an aluminum raw material layer deposited on the transparent substrate through an oxidation process using De-ionized (DI) water.

3. The transparent metal oxide substrate of claim 1,
wherein the n1 is 1.6 to 1.7, and the n2 is 1.1 to 1.5.

4. The transparent metal oxide substrate of claim 1,
wherein the first coating layer has a thickness satisfying a range of 10 to 100 nm, and
the second coating layer has a thickness satisfying a range of 50 to 500 nm.

5. The transparent metal oxide substrate of claim 4,
wherein the second coating layer has a random nano-flake structure consisting of a plurality of unit flakes of which a width gradually decreases toward an upper side thereof.

6. The transparent metal oxide substrate of claim 5,
wherein as the second coating layer has the random nano-flake structure, a refractive index continuously decreases toward the upper side thereof.

7. The transparent metal oxide substrate of claim 1,
wherein the first coating layer and the second coating layer include at least one material selected from a group consisting of aluminum oxide and aluminum hydroxide.

8. The transparent metal oxide substrate of claim 7,
wherein the first coating layer is an aluminum oxide thin film layer, and the second coating layer is an aluminum oxide nanostructure layer.

9. The transparent metal oxide substrate of claim 8,
wherein the first coating layer is a polycrystalline aluminum oxide thin film layer with a grain boundary, and the second coating layer is a polycrystalline aluminum oxide nanostructure layer with a grain boundary.

10. A method of manufacturing a transparent metal oxide substrate, the method comprising:
a first step of preparing a transparent substrate;
a second step of depositing an aluminum raw material layer on the prepared transparent substrate; and
a third step of forming an aluminum compound bilayer by phase-changing the deposited aluminum raw material layer through an oxidation process using DI water.

11. The method of claim 10,
wherein the third step includes:
immersing the transparent substrate on which the aluminum raw material layer is deposited in the DI water at 50 to 100° C.; and
exposing the transparent substrate immersed in the DI water for a predetermined time in a high temperature-high humidity atmosphere of 60 to 80° C. and a relative humidity of 70 to 90%.

12. The method of claim 10,
wherein the aluminum compound bilayer consists of
a first coating layer disposed on the transparent substrate with a refractive index of n1 as a high refractive index compound layer and a second coating layer disposed on the first coating layer with a refractive index of n2 as a low refractive index compound layer, and
wherein the refractive indices satisfy a condition of n1>n2.
